(19) United States
(12) Patent Application Publication
(10) Pub. No.: US 2011/0308458 A1
(43) Pub. Date: Dec. 22, 2011

(54) Thin Film Deposition Apparatus

(75) Inventors: Bo Ramchan Sung, Asan-si (KR); Kyo Woog Koo, Cheonan-si (KR); Jung Keun Cho, Seoul (KR)

(73) Assignee: SEMES CO., LTD., Chungcheongnam-do (KR)

(21) Appl. No.: 13/164,229

(22) Filed: Jun. 20, 2011

(30) Foreign Application Priority Data
Jun. 21, 2010 (KR) 10-2010-0058787
Nov. 11, 2010 (KR) 10-2010-0112263

(51) Int. Cl. C23C 16/455; C23C 16/50; C23C 16/458

(52) U.S. Cl. 118/719; 118/728

(57) ABSTRACT

Provided is a thin film deposition apparatus. The thin film deposition apparatus includes a substrate support unit configured to support a substrate; and a shower head disposed above the substrate support unit to supply a process gas to the substrate. The shower head includes: an upper plate including a plurality of gas channels forming process gas flow paths and gas injection holes formed in the gas channels, high-frequency power being applied to the upper plate to excite the process gas into plasma; a baffle plate disposed under the upper plate and including a plurality of holes to uniformly distribute the process gas; and an injection plate disposed under the baffle plate to inject the process gas supplied through the baffle plate to a substrate.

### CROSS-REFERENCE TO RELATED APPLICATIONS

This U.S. non-provisional patent application claims priority under 35 U.S.C. §119 of Korean Patent Application Nos. 10-2010-0058787, filed on Jun. 21, 2010, and 10-2010-0112263, filed on Nov. 11, 2010, the entire contents of which are hereby incorporated by reference.

### BACKGROUND OF THE INVENTION

The present invention disclosed herein relates to a thin film deposition apparatus, and more particularly, to a plasma enhanced chemical vapor deposition (PECVD) apparatus for depositing a thin film on a substrate using plasma.

Solar cells are used to convert solar energy into electric energy by using semiconductors. Solar cells can be classified into: single crystalline silicon solar cells, polycrystalline solar cells, thin-film solar cells, etc.

Thin-film solar cells are manufactured by depositing p, i, n films on a transparent glass or plastic substrate, and crystalline solar cells are manufactured by depositing an anti-reflection film on a silicon substrate. Such films may be deposited on a substrate through a PECVD process.

### SUMMARY OF THE INVENTION

The present invention provides a thin film deposition apparatus that can be deposit a thin film uniformly.

The present invention is not limited to the aforesaid. The present invention will be clearly understood by those skilled in the art from descriptions below.

Embodiments of the present invention provide thin film deposition apparatus including: a process chamber; a substrate support unit disposed in the process chamber to support a substrate; and a shower head disposed above the substrate support unit to supply a process gas to the substrate, wherein the shower head includes: an upper plate including a plurality of gas channels forming process gas flow paths and gas injection holes formed in the gas channels, high-frequency power being applied to the upper plate to excite the process gas into plasma; a baffle plate disposed under the upper plate and including a plurality of holes to uniformly distribute the process gas; and an injection plate disposed under the baffle plate to inject the process gas supplied through the baffle plate to the substrate.

In some embodiments, the gas channels, the gas injection holes of the upper plate, and the holes of the baffle plate are configured to increase a flow resistance sequentially.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a perspective view illustrating a plasma enhanced chemical vapor deposition (PECVD) apparatus for large substrates according to an embodiment of the present invention;

FIG. 2 is a plan view illustrating the PECVD apparatus for large substrates according to an embodiment of the present invention;

FIG. 3 is a side sectional view illustrating the PECVD apparatus for large substrates according to an embodiment of the present invention;

FIG. 4A is a sectional view illustrating a process chamber in which a susceptor is in a downward position according to an embodiment of the present invention;

FIG. 4B is a sectional view illustrating the process chamber in which the susceptor is in an upward position according to an embodiment of the present invention;

FIG. 5 is a sectional view illustrating a shower head according to an embodiment of the present invention;

FIG. 6 is a view illustrating an upper structure of an upper plate according to an embodiment of the present invention;

FIG. 7 is an enlarge view illustrating a main portion of FIG. 5, according to an embodiment of the present invention; and

FIG. 8 is a view illustrating a modification example of the upper plate according to another embodiment of the present invention.

### DETAILED DESCRIPTION OF PREFERRED EMBODIMENTS

A thin film deposition apparatus will be described below in more detail with reference to the accompanying drawings according to exemplary embodiments of the present invention. Like reference numerals refer to like elements throughout. Moreover, detailed descriptions related to well-known functions or configurations will be ruled out in order not to unnecessarily obscure subject matters of the present invention.

### Embodiments

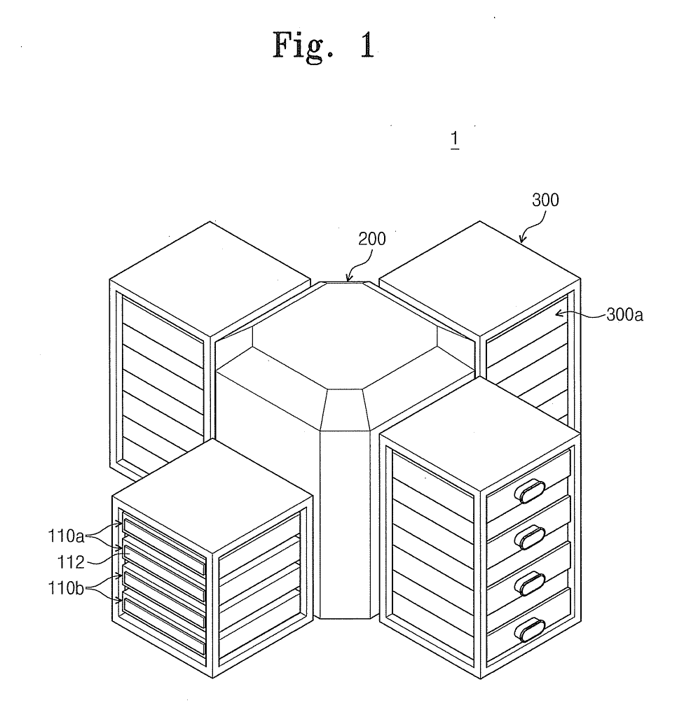

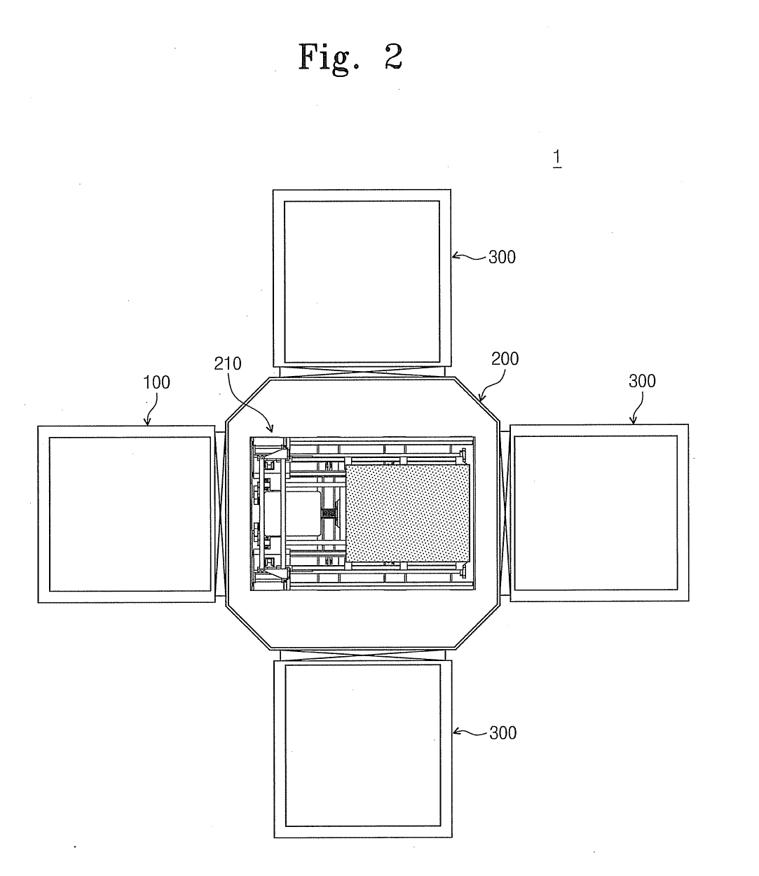

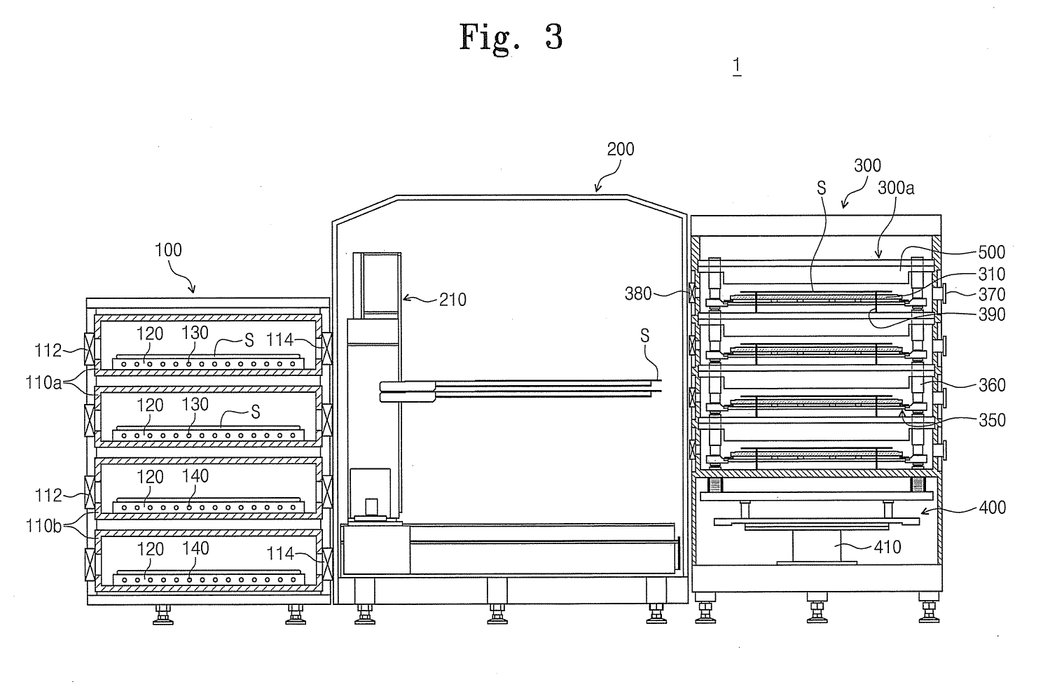

FIG. 1 is a perspective view illustrating a plasma enhanced chemical vapor deposition (PECVD) apparatus 1 for large substrates according to an embodiment of the present invention, and FIGS. 2 and 3 are a plan view and a side sectional view illustrating the PECVD apparatus 1 for Large Substrates According to embodiments of the present invention.

Referring to FIGS. 1 through 3, the PECVD apparatus 1 is used to a PECVD process on large solar cell substrates (S). The PECVD apparatus 1 includes a loadlock chamber 100, a transfer chamber 200, and a plurality of process modules 300.

The loadlock chamber 100 is disposed at a front side of the PECVD apparatus 1. The loadlock chamber 100 includes a stack of four chambers 110a and 110b. The four chambers 110a and 110b may include: two loading chambers 110a in which unprocessed large substrates (S) are placed; and two unloading chambers 110b in which processed large substrates (S) are placed.

Each of the loading chambers 110a and the unloading chambers 110b include a first inlet/outlet port 112, a second inlet/outlet port 114, and an inner stage 120 on which a large substrate (S) can be placed. Pre-heater 130 are disposed at the stages 120 of the loading chambers 110a to heat large substrates (S). Since processed large substrates (S) are placed on the stages 120 of the unloading chambers 110b, coolers 140 are disposed at the stages 120 of the unloading chambers 110b to cool the processed large substrates (S).

Large substrates (S) are loaded into or unloaded from the loading chambers 110a by an atmospheric transfer robot (not shown). When a transfer robot 210 of the transfer chamber 200 loads or unloads large substrates (S), the loading chambers 110a and the unloading chambers 110b of the loadlock chamber 100 are kept in a vacuum state like (similar to) the state of the transfer chamber 200. When the atmospheric transfer robot carries unprocessed large substrates (S) into the loading chambers 110a or processed large substrates (S) out of the unloading chambers 110b, the loading chambers 110a and the unloading chambers 110b are kept in an atmospheric state. That is, the states of the loading chambers 110a and the unloading chambers 110b of the loadlock chamber 100 are changed between vacuum and atmospheric states and kept in the changed state, so as not to change the pressure state of the transfer chamber 200. For rapid pressure change of the loadlock chamber 100, the loadlock chamber 100 is divided into the loading chambers 110a and the unloading chambers 110b. Alternatively, the loadlock chamber 100 may be divided into loading/unloading chambers for using the loading/loading chamber for both loading and unloading.

The transfer chamber 200 is disposed among the loadlock chamber 100 and the process modules 300. The transfer chamber 200 is connected to the loadlock chamber 100 and process chambers 300a of the process modules 300. The transfer chamber 200 includes the transfer robot 210 to carry large substrates (S). The transfer robot 210 may include one or two arms to carry large substrates (S) from the stages 120 of the loading chambers 110a to the process chambers 300a of the process modules 300.

Instead of the transfer robot 210 shown in FIG. 3, any other robot used for manufacturing solar cells or flat display panels may be used. For example, a robot having a double-blade arm for handing two large substrates (S) may be used, or a robot having one or more arms may be used. In addition, a robot having a combination of such arms may be used.

The process modules 300 are disposed around the transfer chamber 200 and connected to lateral sides of the transfer chamber 200. In the current embodiment, three process modules 300 are disposed at right angles around the transfer chamber 200. Alternatively, four or five process modules 300 may be disposed.

In the process modules 300, PECVD processes are performed to deposit thin films on substrates (S) using plasma. Thin films may be deposited on substrates (S) such as transparent glass or plastic substrates used to manufacture thin-film solar cells or silicon substrates used to manufacture crystalline solar cells. For example, the process modules 300 may be used to deposit tandem thin films by sequentially stacking amorphous silicon (a-Si) films and micro-crystalline silicon (mc-Si) films on transparent substrates for thin-film solar cells.

Each of the process modules 300 includes a stack of the process chambers 300a for independently processing substrates (S) by using plasma. In the current embodiment, each of the process modules 300 includes a stack of four process chambers 300a. However, each of the process modules 300 may include five or more process chambers 300a if there is no height limit.

A lift device 400 including a lift driving unit 410 is disposed under the lowermost process chamber 300a. The lift device 400 is used to raise or lower susceptors 310 of the four process chambers 300a at the same time. Raising or lowering forces of the lift device 400 may be transmitted to the susceptors 310 of the process chambers 300a through lift shafts 360.

Owing to the above-described structure of the process modules 300, the height of equipment can be reduced, and thus more process chambers 300a can be stacked.

Since the PECVD apparatus 1 includes a plurality of process chambers 300a (twelve or more process chambers 300a) in a limited space, process and production flexibilities can be improved, and the productivity of the PECVD apparatus 1 can be high. Particularly, the PECVD apparatus 1 may be used to manufacture tandem solar cells by successively depositing a-Si films and mc-Si films which require relatively long deposition time due to a relatively large deposition thickness of about 20,000 Å (2 μm) or less.

Since tandem solar cells have a stack structure of a-Si film and an mc-Si film, the tandem solar cells can efficiently absorb sunlight from infrared to ultraviolet, and thus the power generating efficiency of the tandem solar cells can be high.

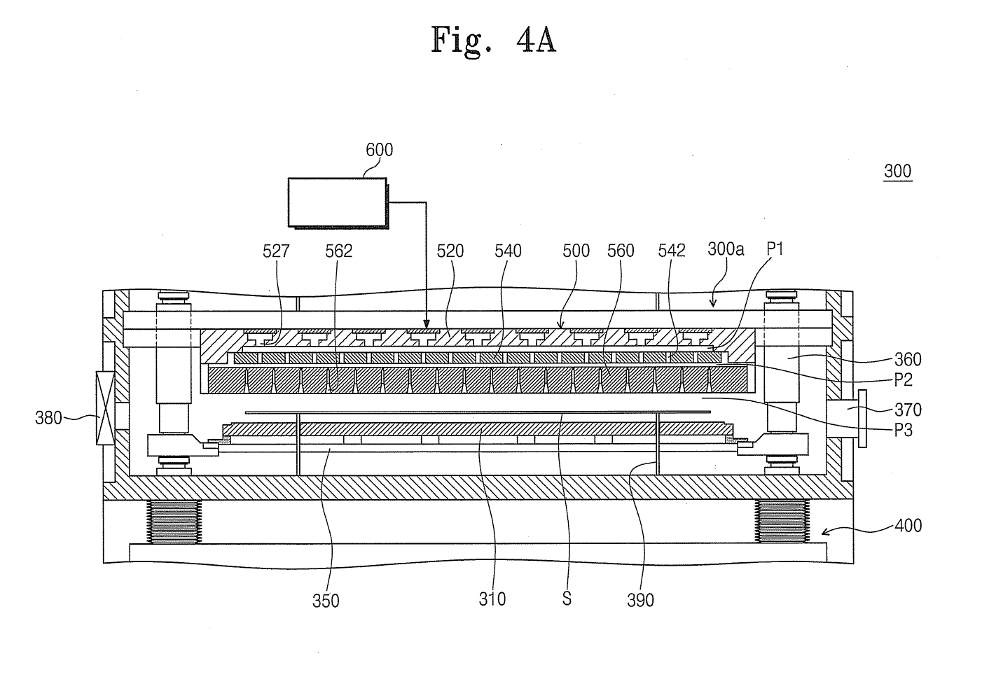

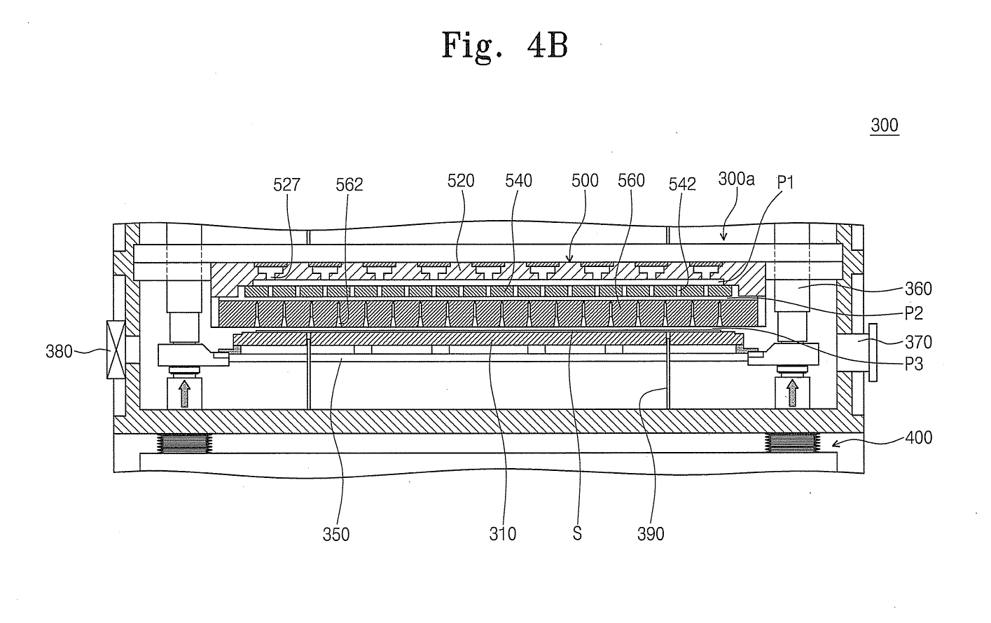

FIG. 4A is a sectional view illustrating the process chamber 300a in which the susceptor 310 is in a downward position according to an embodiment of the present invention, and FIG. 4B is a sectional view illustrating the process chamber 300a in which the susceptor 310 is in an upward position according to an embodiment of the present invention.

Referring to FIGS. 4A and 4B, the process chamber 300a provides a process region (reaction region) between the susceptor 310 and a shower head 500. In the same process module 300, the process region of the process chamber 300a is opened. That is, in the same process module 300, the process region of the process chamber 300a is not completely isolated from plasma generating regions of the other process chambers 300a.

A slot valve 380 is disposed at a lateral wall of the process chamber 300a to connect or disconnect the reaction region to or from the transfer chamber 200. When a large substrate (S) is carried from the transfer chamber 200 to the susceptor 310 or a large substrate (S) is carried from the susceptor 310 to the transfer chamber 200, the slot valve 380 is opened.

Lift pins 390 are disposed at the susceptor 310 to support a large substrate (S) when the large substrate (S) is carried to or from the susceptor 310. The lift pins 390 support a large substrate (S) when the susceptor 310 is moved downward. That is, when the transfer robot 210 carries a large substrate (S), the susceptor 310 is at a downward position, and the large substrate (S) is placed on the lift pins 390. Then, the susceptor 310 is moved upward to support the large substrate (S). For this, the lift pins 390 are inserted in pin holes of the susceptor 310.

The shower head 500 is an electrode type shower head disposed above the susceptor 310, and a high-frequency power source (not shown) is connected to the shower head 500 to apply a high-frequency current for generating plasma.

A gas supply unit 600 supplies a predetermined gas mixture to the shower head 500 according to a process to be performed in the process chamber 300a, and plasma is generated from the gas mixture to deposit a thin film on a large substrate (S). In detail, the gas mixture is excited into plasma in the shower head 500 to form a predetermined thin film on the large substrate (S), and then the gas mixture is discharged through a gas exhaust pipe 370.

The susceptor 310 is vertically movable in the process chamber 300a and is electrically grounded. A large substrate (S) is placed on the susceptor 310. A heater (not shown) is disposed in the susceptor 310 to heat the large substrate (S). The bottom surface of the susceptor 310 is supported by a susceptor support 350. The susceptor support 350 is wider than the susceptor 310, and the lift shafts 360 are vertically disposed at both sides of the susceptor support 350. The lift shafts 360 are inserted through the shower head 500 and are connected to the lift shafts 360 of the upper process chamber 300a. That is, a lifting force of the lift device 400 can be transmitted through the lift shafts 360. The lowermost lift shafts 360 are connected to the lift device 400. A lifting force of the lift device 400 is transmitted to the respective process chambers 300a through the lift shafts 360 so that the susceptors 310 of the process chambers 300a can be simultaneously lifted.

For example, a mixture of a source gas and a reaction gas may be supplied to the shower head 500. The source gas includes a main component of a thin film that will be formed on a substrate (S), and the reaction gas is included in the mixture for exciting the mixture into plasma. For example, if a silicon oxide film is deposited on a substrate (S), SiH₄ may be used as a source gas, and O₂ may be used as a reaction gas. In another example, if a silicon nitride film is deposited on a substrate (S), SiH₄ may be used as a source gas, and NH₃ or N₂ may be used as reaction gas. In another example, if an amorphous silicon film is deposited on a substrate (S), SiH₄ may be used as a source gas, and H₂ may be used as a reaction gas.

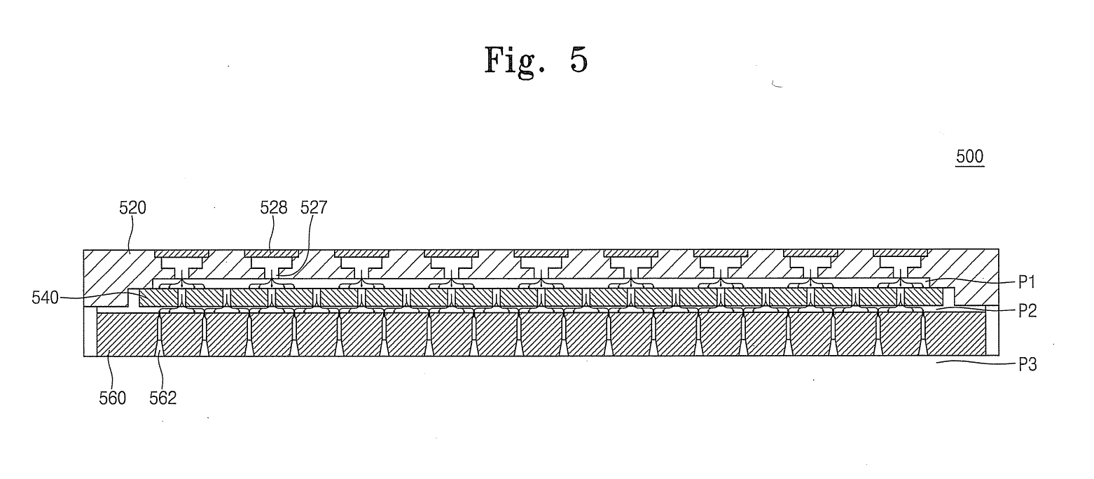

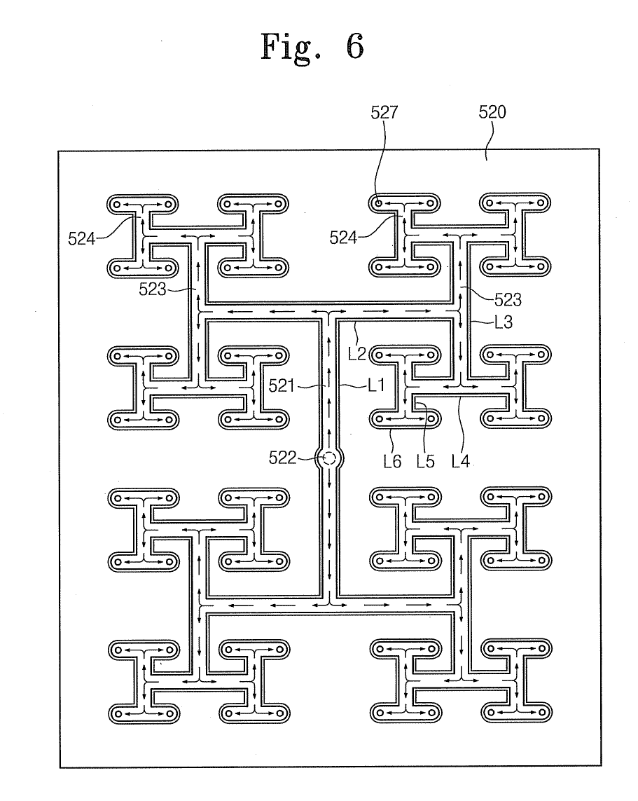

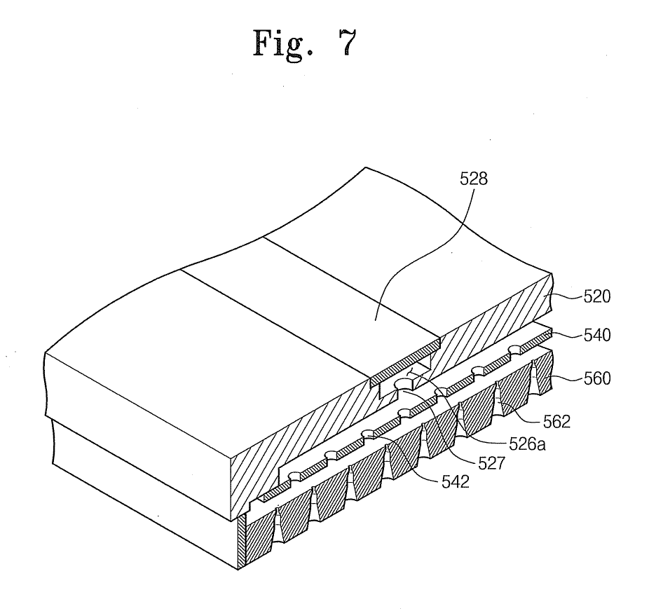

FIG. 5 is a sectional view illustrating the shower head 500 according to an embodiment of the present invention, and FIG. 6 is a view illustrating an upper structure of an upper plate 520 according to an embodiment of the present invention. FIG. 7 is an enlarge view illustrating a main portion of FIG. 5 according to an embodiment of the present invention.

Referring to FIGS. 5 through 7, the shower head 500 includes the upper plate 520, a baffle plate 540, and an injection plate 560.

The baffle plate 540 is coupled to the bottom side of the upper plate 520, and a predetermined gap is formed between the baffle plate 540 and the upper plate 520. A plurality of gas holes 542 (refer to FIG. 4A or 4B) are Banned in the baffle plate 540. The injection plate 560 is disposed under the baffle plate 540, and a plurality of injection holes 562 are formed in the injection plate 560. Gas supplied through the upper plate 520 flows through the gas holes 542 of the baffle plate 540 and is then injected to a large substrate (S) through the injection holes 562 of the injection plate 560.

The upper plate 520 may have a rectangular shape. High-frequency power source (not shown) capable of supplying power in the very high frequency (VHF) range of 30 MHz to 300 MHz is connected to the upper plate 520 to generate plasma.

A plurality of gas channels are formed in the topside of the upper plate 520 so that gas supplied to the upper plate 520 can flow uniformly. The gas channels of the upper plate 520 include first to sixth lines L1 to L6. The first line L1 is formed in a center region of the topside of the upper plate 520, and an inlet groove 522 is formed at a center of the first line L1 so that gas supplied to the upper plate 520 through the gas inlet groove 522 can flow to both ends of the first line L1. The second lines L2 branch off from both ends of the first line L1 in directions perpendicular to the first line L1. The third lines L3 branch off from ends of the second lines L2 in directions perpendicular to the second lines L2. The fourth lines L4 branch off from both ends of the third lines L3 in directions perpendicular to the third lines L3. The fifth lines L5 branch off from both ends of the fourth lines L4 in directions perpendicular to the fourth lines L4. The sixth lines L6 are connected to both ends of the fifth lines L5 and are perpendicular to the fifth lines L5. Gas injection holes 527 are formed at both ends of the sixth lines L6.

First channels 521 having a T-shape are formed in a center region of the topside of the upper plate 520 by the first line L1 and the second lines L2. The gas inlet groove 522 is connected to vertical portions (the first line L1) of the first channels 521 to supply gas to the upper plate 520. The plurality of channels of the upper plate 520 are symmetric with respect to the center of the upper plate 520 and are arranged in a rectangular shape. Thus, only some of the symmetric channels will be described below.

T-shaped second channels 523 formed by the third and fourth lines L3 and L4 are connected to ends of horizontal portions (the second lines L2) of the first channels 521. Third channels 524 formed by the fifth and sixth lines L5 and L6 are connected to ends of horizontal portions (the fourth lines L4) of the T-shaped second channels 523. The gas injection holes 527 are formed through both ends of horizontal portions (the sixth lines L6) of the third channels 524 so that gas can pass through the gas injection holes 527. The first, second, and third channels 521, 523, and 524 include stepped portions, and cover plates 528 are coupled to the stepped portions. Thus, gas flow paths are formed between the bottom surfaces of the cover plates 528 and the bottom sides of the first to third channels 521, 523, and 524.

Gas flows in the shower head 500 as follows. Gas (SiH₄ and H₂) is supplied to the center of the upper plate 520 through the gas inlet groove 522. Next, the gas flows into sixty four branch paths of the first to third channels 521, 523, and 524 (primary flow dividing). Next, the gas flows through the sixty four gas injection holes 527 toward a first baffle space B1 between the upper plate 520 and the baffle plate 540. Thereafter, the gas flows through the gas holes 542 of the baffle plate 540 (secondary flow dividing) toward a second baffle space B2 between the baffle plate 540 and the injection plate 560. Finally, the gas is uniformly injected to a large substrate (S) through the injection holes 562 of the injection plate 560.

For uniform gas supply, the aperture ratios of the upper plate 520, the baffle plate 540, and the injection plate 560 may be as follows. The aperture ratio C2 of the gas holes 542 of the baffle plate 540 may be smaller than the aperture ratio C1 of the gas injection holes 527 of the upper plate 520 and the aperture ratio C3 of the injection holes 562 of the injection plate 560 (C2<C1, C3). For example, the pressure P3 of the process region is substantially equal to the pressure P2 of the second baffle space B2, and the pressure P1 of the first baffle space B1 is greater than the pressure P3 of the process region and the pressure P2 of the second baffle space B2 (P1>P2, P2=P3).

In the shower head 500 of the present invention, a plurality of gas channels are formed in the topside of the upper plate 520 to which gas is first supplied. Therefore, gas can uniformly flow in the upper plate 520. Furthermore, gas may be uniformly supplied to the first baffle space B1 and the second baffle space B2. Owing to this, the height of the first baffle space B1 formed between the upper plate 520 and the baffle plate 540 can be reduced, and the height of the second baffle space B2 formed between the baffle plate 540 and the injection plate 560 can be reduced. Therefore, the shower head 500 can have a small thickness, and thus the height of the process chamber 300a can be reduced. Thus, more process chambers 300a can be stacked in the same process module 300.

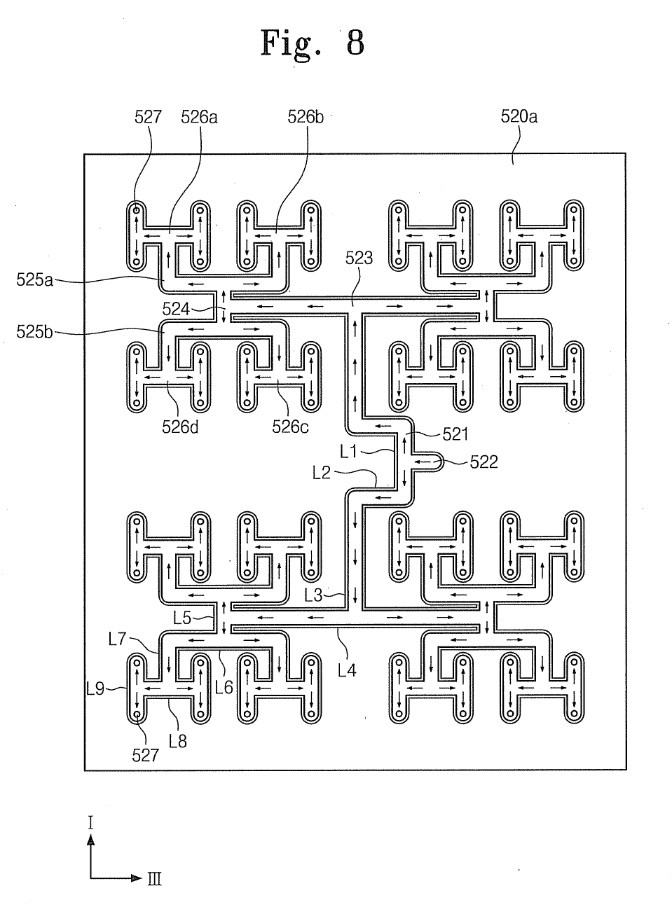

FIG. 8 is a view illustrating a modification example of the upper plate 520 according to another embodiment of the present invention.

Referring to FIG. 8, a plurality of gas channels are formed in the topside of an upper plate 520a so that gas supplied to the upper plate 520a can flow uniformly. The gas channels of the upper plate 520a include first to ninth lines L1 to L9. The first line L1 is formed in a center region of the topside of the upper plate 520a, and an inlet groove 522 is formed at a center of the first line L1 so that gas supplied to the upper plate 520a through the gas inlet groove 522 can flow to both ends of the first line L1. The second lines L2 are connected to both ends of the first line L1 and are perpendicular to the first line L1. The third lines L3 are connected to ends of the second lines L2 and are perpendicular to the second lines L2. The fourth lines L4 branch off from ends of the third lines L3 in directions perpendicular to the third lines L3. The fifth lines L5 branch off from both ends of the fourth lines L4 and are perpendicular to the fourth lines L4. The sixth lines L6 branch off from both ends of the fifth lines L5 and are perpendicular to the fifth lines L5. The seventh lines L7 are connected to both ends of the sixth lines L6 and are perpendicular to the sixth lines L6. The eighth lines L8 branch off from ends of the seventh lines L7 and are perpendicular to the seventh lines L7. The ninth lines L9 branch off from both ends of the eighth lines L8 and are perpendicular to the eighth lines L8. Gas injection holes 527 are formed in both ends of the ninth lines L9.

A first channel 521 having a ⊃-shape is formed in a center region of the topside of the upper plate 520a by the first line L1 and the second lines L2. The gas inlet groove 522 extends from a vertical portion (the first line L1) of the first channel 521 to supply gas to the upper plate 520a. The plurality of channels of the upper plate 520a are symmetrically arranged around the first channels 521. Thus, only some of the symmetric channels will be described below.

T-shaped second channels 523 formed by the third and fourth lines L3 and L4 are connected to ends of horizontal portions (the second lines L2) of the first channels 521. Third channels 524 formed by the fifth lines are connected to ends of horizontal portions (the fourth lines L4) of the T-shaped second channels 523. D-shaped fourth channels 525a and 525b formed by the sixth and seventh lines L6 and L7 are connected to both ends of the third channels 524. H-shaped fifth channels 526a, 526b, 526c, and 526d are connected to both ends of the fourth channels 525a and 525b. The gas injection holes 527 are formed through both ends of vertical portions (the ninth lines L9) of the fifth channels 526a, 526b, 526c, and 526d. The first to fifth channels include stepped portions, and cover plates 528 are coupled to the stepped portions. Thus, gas flow paths are formed between the bottom surfaces of the cover plates 528 and the bottom sides of the first to fifth channels.

Gas flows in the shower head 500 as follows. Gas (SiH₄ and H₂) is supplied to the center of the upper plate 520a through the gas inlet groove 522. Next, the gas flows into sixty four branch paths of the first to fifth channels (primary flow dividing). Next, the gas flows through the sixty four gas injection holes 527 toward the first baffle space B1 between the upper plate 520a and the baffle plate 540. Thereafter, the gas flows through the gas holes 542 of the baffle plate 540 (secondary flow dividing) toward the second baffle space B2 between the baffle plate 540 and the injection plate 560. Finally, the gas is uniformly injected to a large substrate (S) through the injection holes 562 of the injection plate 560.

According to the present invention, under a VHF power condition (30 MHz to 300 MHz) and a high pressure condition of about 1 Torr to 10 Torr (denser plasma can be obtained as the pressure increases because the possibility of collision between electrons and neutral gas increases), an mc-Si film may be deposited on a large substrate (S) (for example, 1100*1400 mm) where an a-Si film is deposited. Particularly, according to the present invention, film thickness uniformity can be improved along the entire area of a substrate (S). High-frequency voltage and high pressure conditions may be necessary for deposition of mc-Si films.

As described above, according to the present invention, a thin film can be deposited on a substrate more uniformly by supply a process gas to the substrate more uniformly.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A thin film deposition apparatus comprising:
a susceptor configured to support a substrate; and
a shower head disposed above the susceptor to supply process gas to the substrate and function as an electrode,
wherein the shower head comprises:
an upper plate comprising a plurality of gas channels and gas injection holes formed in the gas channels, the gas channels being arranged on the same plane to provides flow paths for the process gas; and
an injection plate disposed under the upper plate and comprising injection holes so as to inject the process gas supplied through the upper plate to the substrate.

2. The thin film deposition apparatus of claim 1, wherein the upper plate comprises:
T-shaped first channels symmetrically arranged with respect to a center of a top surface of the upper plate at which an inlet hole is formed to introduce gas, the first channels branching off from the inlet hole in both directions;
T-shaped second channels perpendicularly connected to both ends of the first channels and branching off into two parts; and
T-shaped third channels perpendicularly connected to both ends of the second channels and branching off into two parts,
wherein the gas introduced through the inlet hole flows in sixty four branch paths provided by the first to third channels.

3. The thin film deposition apparatus of claim 2, wherein the gas injection holes are formed through ends of the third channels.

4. The thin film deposition apparatus of claim 2, wherein the first to third channels comprise stepped portions, and the thin film deposition apparatus further comprises cover plates coupled to the stepped portions to form gas flow paths.

5. The thin film deposition apparatus of claim 1, wherein the upper plate comprises:
a first line disposed at a center region of a top surface of the upper plate, an inlet hole being connected to a center portion of the first line;
second lines perpendicularly branching off from both ends of the first line;
third lines perpendicularly branching off from ends of the second lines;
fourth lines perpendicularly branching off from ends of the third lines;
fifth lines perpendicularly branching off from ends of the fourth lines; and
sixth lines perpendicularly branching off from ends of the fifth lines,
wherein the gas injection holes are formed through ends of the sixth lines.

6. The thin film deposition apparatus of claim 1, wherein the upper plate comprises:
a first channel formed in a center region of a top surface of the upper plate and connected to an inlet hole through which gas is introduced
T-shaped second channels perpendicularly connected to both ends of the first channel and branching off into two parts;
third channels connected to both ends of the T-shaped second channels and branching off into two parts;
⊃-shaped fourth channels perpendicularly connected to both ends of the third channels and branching off into two parts; and
H-shaped fifth channels perpendicularly connected to both ends of the ⊃-shaped fourth channels and branching off into four parts,
wherein the gas introduced through the inlet hole flows in sixty four branch paths provided by the first to fifth channels.

7. The thin film deposition apparatus of claim 1, wherein the shower head further comprises a baffle plate between the upper plate and the injection plate, and the baffle plate comprises a plurality of holes to uniformly distribute the process gas,
wherein a first baffle space is formed between the baffle plate and the upper plate, and a second baffle space is formed between the baffle plate and the injection plate.

8. The thin film deposition apparatus of claim 7, wherein the gas channels, the gas injection holes of the upper plate, and the holes of the baffle plate are configured to increase a flow resistance sequentially.

9. The thin film deposition apparatus of claim 7, wherein an aperture ratio of the holes of the baffle plate is smaller than an aperture ratio of the gas injection holes of the upper plate and an aperture ratio of the injection holes of the injection plate.

10. The thin film deposition apparatus of claim 2, wherein the upper plate has a rectangular shape, and a high-frequency power source having a frequency range of 30 MHz to 300 MHz is connected to the upper plate to generate plasma.

11. A thin film deposition apparatus comprises:
an upper plate to which a high-frequency power source is connected so as to generate plasma, the upper plate comprising a plurality of symmetric gas channels formed on the same plane so as to primarily divide a flow of process gas, gas injection holes being formed in ends of the gas channels to inject the process gas;
a baffle plate disposed under the upper plate to form a first baffle space, the baffle plate comprising a plurality of holes so as to secondarily divide flows of the process gas;
an injection plate disposed under the baffle plate to form a second baffle space, the injection plate comprising injection holes to inject the process gas; and
a susceptor disposed under the injection plate to support a substrate.

12. A thin film deposition apparatus comprising:
a loadlock chamber configured to accommodate substrates;
a transfer chamber connected to the loadlock chamber and comprising a transfer robot to carry substrates; and
process modules connected to the transfer chamber, each of the process modules comprising at least two vertically stacked process chambers to perform a plasma process on substrates;
wherein each of the process chambers comprises:
a susceptor configured to place a semiconductor substrate thereon; and
a shower head disposed above the susceptor and comprising a stack of an upper plate, a baffle plate, and an injection plate,
wherein a first baffle space is formed between the upper plate and the baffle plate, and a second baffle space is aimed between the baffle plate and the injection plate,
wherein the upper plate comprises gas channels formed on the same plane to provide process gas flow paths, and process gas is uniformly supplied to the first baffle space through the process gas flow paths.

13. The thin film deposition apparatus of claim 12, wherein the upper plate comprises:
T-shaped first channels symmetrically arranged with respect to a center of a top surface of the upper plate at which an inlet hole is formed to introduce gas, the first channels branching off from the inlet hole in both directions;
T-shaped second channels perpendicularly connected to both ends of the first channels and branching off into two parts; and
T-shaped third channels perpendicularly connected to both ends of the second channels and branching off into two parts,
wherein the gas introduced through the inlet hole flows in sixty four branch paths provided by the first to third channels.

14. The thin film deposition apparatus of claim 13, wherein the gas channels, gas injection holes of the upper plate, and holes of the baffle plate are configured to increase a flow resistance sequentially.

15. The thin film deposition apparatus of claim 13, wherein an aperture ratio of holes of the baffle plate is smaller than an aperture ratio of gas injection holes of the upper plate and an aperture ratio of injection holes of the injection plate.

16. The thin film deposition apparatus of claim 13, wherein the process modules and the loadlock chamber are arranged around the transfer chamber in radial directions.

17. The thin film deposition apparatus of claim 13, wherein each of the process modules comprises:
a lift device disposed under a lowermost process chamber and comprising a lift driving unit; and
lift shafts vertically disposed at both sides of the susceptor so as to be lifted together with the susceptor by the lift device,
wherein upper ends of the lift shafts are inserted through the shower head and are connected to lift shafts of an upper process chamber so that a lifting force of the lift device is transmitted through the lift shafts.
